(19) United States
(12) Patent Application Publication
(10) Pub. No.: US 2012/0025299 A1
(43) Pub. Date: Feb. 2, 2012

(54) METHOD FOR FABRICATING SEMICONDUCTOR DEVICE WITH BURIED GATES

(76) Inventor: Soo-Byung KO, Gyeonggi-do (KR)

(21) Appl. No.: 12/945,249

(22) Filed: Nov. 12, 2010

(30) Foreign Application Priority Data
Jul. 30, 2010 (KR) 10-2010-0074254

(51) Int. Cl. H01L 29/78; H01L 21/28

(52) U.S. Cl. 257/330; 438/585; 438/589; 257/E21.19; 257/E29.262

(57) ABSTRACT

A method for fabricating a semiconductor device includes forming an insulation layer, hydroxylating a surface of the insulation layer by performing a pre-treatment, forming an adhesive layer over the insulation layer, performing a post-treatment, and forming a conductive layer over the adhesive layer.

### CROSS-REFERENCE TO RELATED APPLICATIONS

The present application claims priority of Korean Patent Application No. 10-2010-0074254, filed on Jul. 30, 2010, which is incorporated herein by reference in its entirety.

### BACKGROUND OF THE INVENTION

Exemplary embodiments of the present invention relate to a semiconductor device fabrication technology, and more particularly, to a method for fabricating a semiconductor device with buried gates.

Because semiconductor devices are highly integrated and fabrication processes are desired to be performed with margins of error under 30 nm, it is difficult to form patterns. Particularly, with regards to Dynamic Random Access Memory (DRAM), the industry is making efforts to increase the height of storage nodes to secure a desired capacitance. However, the height of the storage node cannot be improved infinitely. The industry is trying to secure a capacitance by decreasing the capacitance of bit lines to secure sensing margins, and a part of such efforts is a technology of forming buried gates (BG).

FIGS. 1A to 1C are cross-sectional views illustrating a conventional method for fabricating a semiconductor device with buried gates. FIGS. 2A and 2B show images revealing disadvantages of the conventional semiconductor device fabrication method.

Referring to FIG. 1A, a hard mask pattern 14 is formed over a substrate 11 in which active regions 13 are defined by an isolation layer 12. Subsequently, a plurality of trenches 15 are formed by etching the substrate 11 with the hard mask pattern 14 as an etch barrier.

Referring to FIG. 1B, a gate insulation layer 16 is formed on the surface of the plurality of the trenches 15. Subsequently, a first gate conductive layer 17 is formed along the surface of the substrate structure with the gate insulation layer 16 formed in the trenches 15. Subsequently, a second gate conductive layer 18 is formed to completely gap-fill the plurality of the trenches 15 over the first gate conductive layer 17.

Referring to FIG. 1C, a gate electrode 19 which fills a portion of each trench 15 is formed by etching the first gate conductive layer 17 and the second gate conductive layer 18 through a blanket etch process. Herein, the gate electrode 19 is formed of a first gate electrode 17A and a second gate electrode 18A.

Subsequently, a sealing layer 20 is formed over the gate electrode 19 to fill the remaining unfilled portion of each trench 15.

According to the conventional technology, the gate insulation layer 16 may be a silicon oxide (SiO₂) layer, the first gate electrode 17A may be a titanium nitride (TiN) layer, and the second gate electrode 18A may be a tungsten (W) layer. Herein, when a single layer of tungsten is formed and used as the gate electrode 19, the resistance of the gate electrode 19 may be decreased in comparison to a double layer of a titanium nitride layer and a tungsten layer stacked therein. However, since a tungsten layer has poor adhesion to a silicon oxide layer, which is the gate insulation layer 16, the tungsten layer may be peeled off, which is a serious concern. For this reason, the gate electrode 19 has been formed as a double layer of a titanium nitride layer and a tungsten layer stacked therein.

Meanwhile, when the gate electrode 19 is formed as a double layer of different materials, i.e., a titanium nitride layer and a tungsten layer, uniformity may be decreased due to the difference in etch selectivity during an etch process and a cleaning process that are performed to form the gate electrode 19. Also, there is further concern that an additional process for securing a predetermined level of resistivity between buried gates is required.

To address the concerns, a technology of forming the gate electrode 19 as a single layer formed of a titanium nitride which has excellent adhesion to a silicon oxide layer, which is used for the gate insulation layer 16, has been suggested.

The technology, however, has a disadvantage in that voids occur between the gate insulation layer 16 and a titanium nitride layer after repeated thermal processes at a temperature of over 750° C. (see FIG. 2B). Although there is little concern just after the titanium nitride layer is deposited over the gate insulation layer 16 (see FIG. 2A), the voids eventually increase the resistivity of the buried gates to deteriorate the characteristics of a semiconductor device (see FIG. 2B).

Therefore, in order to use a single layer of a titanium nitride as the gate electrode 19, a method of maintaining stable interface conditions between the gate insulation layer 16 and the titanium nitride layer during the subsequent thermal processes while increasing the adhesion between the gate insulation layer 16 and the titanium nitride layer is desired.

### SUMMARY OF THE INVENTION

An embodiments of the present invention is directed to a method for fabricating a semiconductor device that may maintain stable interface conditions between a gate insulation layer and a gate electrode during subsequent thermal processes while increasing the adhesion between the gate insulation layer and the gate electrode.

In accordance with an embodiment of the present invention, a method for fabricating a semiconductor device includes forming an insulation layer, hydroxylating a surface of the insulation layer by performing a pre-treatment, forming an adhesive layer over the insulation layer, performing a post-treatment, and forming a conductive layer over the adhesive layer.

The insulation layer may include a silicon oxide layer (SiO₂).

The performing of the pre-treatment may include performing a primary pre-treatment where hydrogen gas (H₂) is applied to the surface of the insulation layer, and performing a secondary pre-treatment by using a mixed solution of hydrogen peroxide (H₂O₂) and deionized water (DI, H₂O). The primary pre-treatment may be performed at a temperature ranging from approximately 700° C. to approximately 1,200° C. under the pressure of approximately 100 mtorr to approximately 450 torr. The secondary pre-treatment may be performed by adding aqueous ammonia to the mixed solution. The secondary pre-treatment may be performed for approximately 5 minutes to approximately 30 minutes.

The adhesive layer may include an early transition metal. The forming of the adhesive layer may be performed by using a mixture of the early transition metal and at least one selected from the group consisting of hydrogen (H), chloride (CI), bromine (Br), and alkoxide, as a source gas. The early transition metal may include one selected from the group consisting of titanium (Ti), zirconium (Zr), hafnium (Hf), vanadium (V), niobium (Nb), and tantalum (Ta).

The performing of the post-treatment may include performing a primary post-treatment in which the adhesive layer is etched until the adhesive layer reaches a certain thickness, and performing a secondary post-treatment by using a mixed gas of hydrogen gas (H₂) and ammonia gas (NH₃). The primary post-treatment may be performed by using one selected from the group consisting of sulfuric acid, perchloric acid (HClO₄), hydroiodic acid (HI), hydrobromic acid (HBr), hydrochloric acid (HCl), and nitric acid (NHO₃). The secondary post-treatment may be performed at a temperature ranging from approximately 700° C. to approximately 1,200° C. under the pressure of approximately 100 mtorr to approximately 450 torr.

The conductive layer may include a titanium nitride layer (TiN).

In accordance with another embodiment of the present invention, a method for fabricating a semiconductor device includes forming a plurality of trenches by selectively etching a substrate, forming a gate insulation layer on the plurality of the trenches, hydroxylating a surface of the gate insulation layer by performing a pre-treatment, forming an adhesive layer over the gate insulation layer, performing a post-treatment, and forming a gate electrode which fills a portion of each trench over the adhesive layer.

The gate insulation layer may include a silicon oxide layer (SiO₂).

The performing of the pre-treatment may include performing a primary pre-treatment where hydrogen gas (H₂) is applied to the surface of the gate insulation layer, and performing a secondary pre-treatment by using a mixed solution of hydrogen peroxide (H₂O₂) and deionized water (DI, H₂O). The primary pre-treatment may be performed at a temperature ranging from approximately 700° C. to approximately 1,200° C. under the pressure of approximately 100 mtorr to approximately 450 torr. The secondary pre-treatment may be performed by adding aqueous ammonia to the mixed solution. The secondary pre-treatment may be performed for approximately 5 minutes to approximately 30 minutes.

The adhesive layer may include an early transition metal. The forming of the adhesive layer may be performed by using a mixture of the early transition metal and at least one selected from the group consisting of hydrogen (H), chloride (CI), bromine (Br) and alkoxide as a source gas. The early transition metal may include one selected from the group consisting of titanium (Ti), zirconium (Zr), hafnium (Hf), vanadium (V), niobium (Nb), and tantalum (Ta).

The performing of the post-treatment may include performing a primary post-treatment in which the adhesive layer is etched until the adhesive layer reaches a predetermined thickness, and performing a secondary pre-treatment by using a mixed gas of hydrogen gas (H₂) and ammonia gas (NH₃). The certain thickness of the adhesive layer is a thickness ranging from approximately 1 nm to approximately 5 nm. The primary post-treatment may be performed by using one selected from the group consisting of sulfuric acid, perchloric acid (HClO₄), hydroiodic acid (HI), hydrobromic acid (HBr), hydrochloric acid (HCl), and nitric acid (NHO₃). The secondary post-treatment may be performed at a temperature ranging from approximately 700° C. to approximately 1,200° C. under the pressure of approximately 100 mtorr to approximately 450 torr.

In accordance with yet another exemplary embodiment of the present invention, a semiconductor device includes a substrate having a trench, a hydroxylated gate insulation layer in the trench, an adhesive layer over the hydroxylated gate insulation layer, and a gate electrode, which fills a portion of the trench over the adhesive layer.

Here, the hydroxylated gate insulation layer may include a silicon oxide layer (SiO₂), the adhesive layer may include an early transition metal, and the gate electrode may include a titanium nitride layer (TiN).

### BRIEF DESCRIPTION OF THE DRAWINGS

FIGS. 1A to 1C are cross-sectional views illustrating a conventional method for fabricating a semiconductor device with buried gates.

FIGS. 2A and 2B are images showing concerns regarding the conventional semiconductor device fabrication method.

FIGS. 3A to 3F are cross-sectional views illustrating a method for fabricating a semiconductor device in accordance with an embodiment of the present invention.

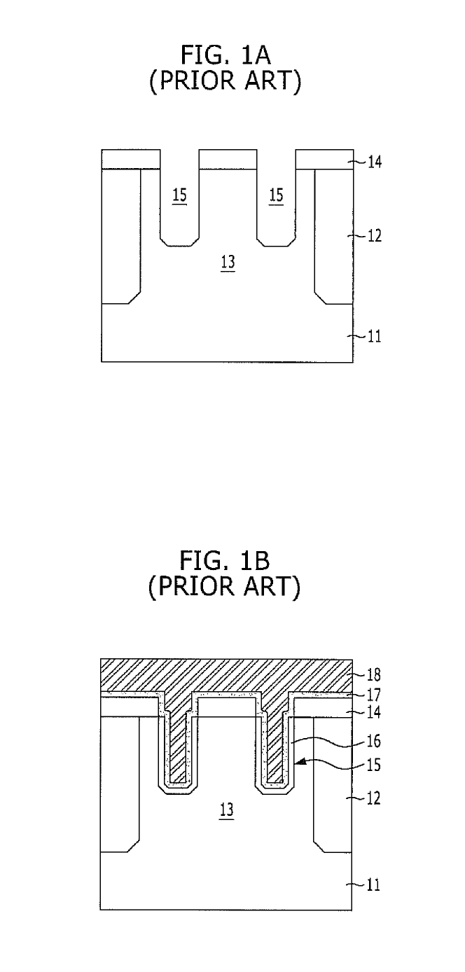

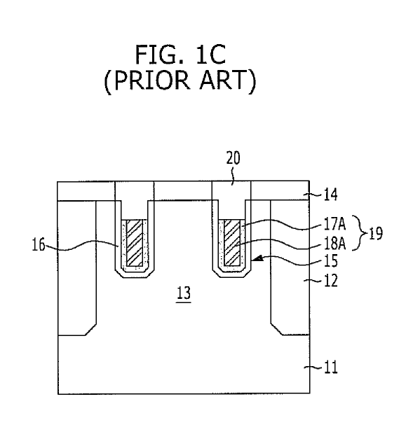

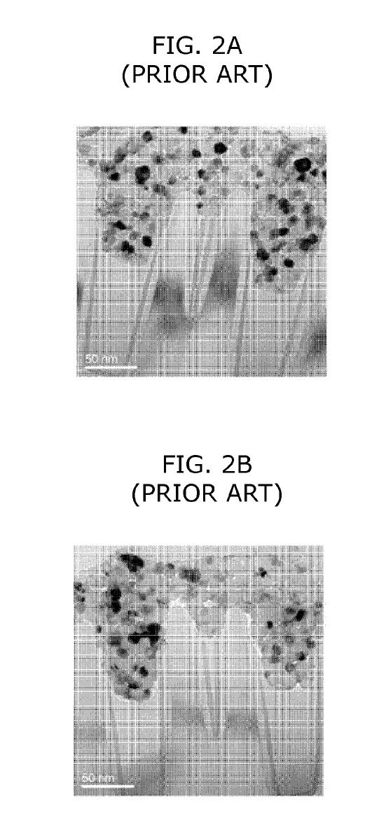

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

The technology of the present invention provides a method for fabricating a semiconductor device that may maintain stable interface conditions between a gate insulation layer and a gate electrode during a subsequent thermal process while increasing the adhesion between the gate insulation layer and the gate electrode at the same time. To this end, an adhesive layer is interposed between a gate electrode and a gate insulation layer, and the binding force and interface characteristics of the adhesive layer are improved through a pre-treatment and a post-treatment.

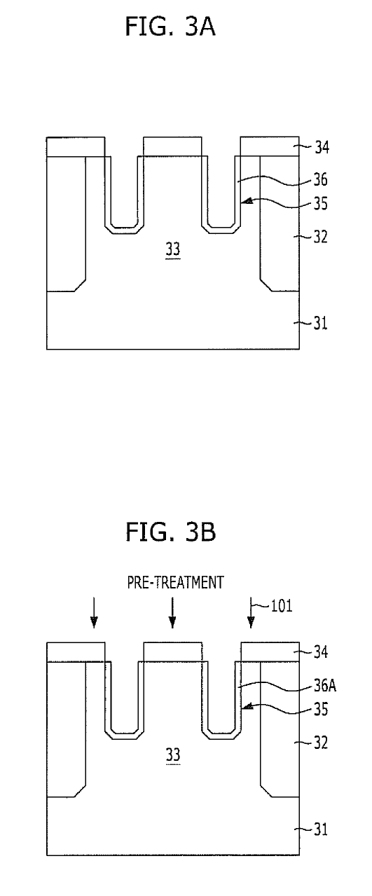

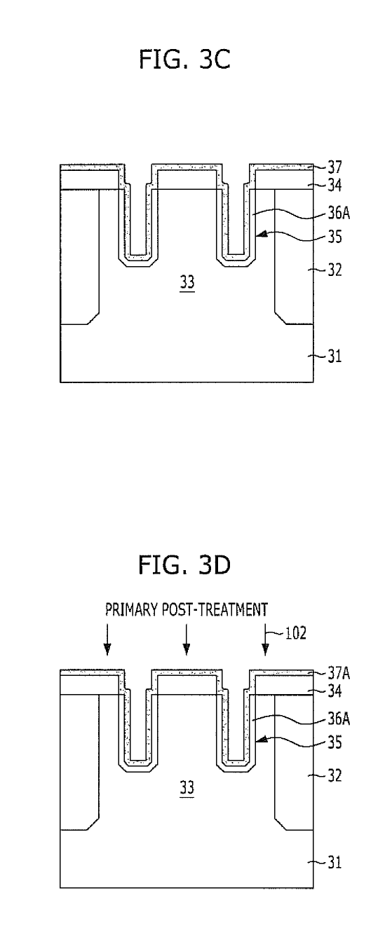

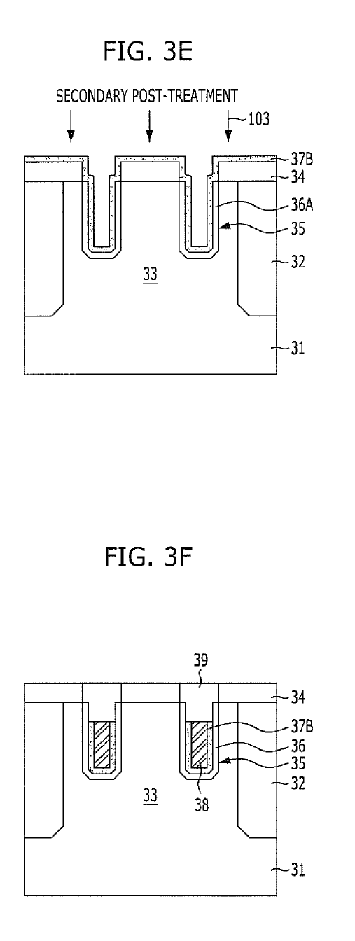

FIGS. 3A to 3F are cross-sectional views illustrating a method for fabricating a semiconductor device in accordance with an exemplary embodiment of the present invention.

Referring to FIG. 3A, a plurality of active regions 33 are defined over a substrate 31 by forming an isolation layer 32. The substrate 31 may include a silicon substrate, and the isolation layer 32 may be formed through a Shallow Trench Isolation (STI) process.

Subsequently, after a hard mask pattern 34 is formed over the substrate 31, a plurality of trenches 35 are formed by etching the substrate 31 with the hard mask pattern 34 used as an etch barrier. The hard mask pattern 34 may be an insulation layer or a conductive layer. The insulation layer may include any one layer or more than two layers selected from the group consisting of an oxide layer, a nitride layer, and an oxynitride layer. The conductive layer may include a polysilicon layer, a silicon germanium layer, and/or a metal layer.

Subsequently, a gate insulation layer 36 is formed on the surface of the plurality of the trenches 35. Herein, the gate insulation layer 36 may be formed as an oxide layer, such as, silicon oxide (SiO₂) layer. The silicon oxide layer may be formed through a thermal oxidation.

Referring to FIG. 3B, a pre-treatment 101 is performed to hydroxylate the surface of the gate insulation layer 36. In other words, a hydroxyl group (—OH) is fixed (or attached) on the surface of the gate insulation layer 36. Hereafter, the hydroxylated gate insulation layer 36 is denoted with reference numeral ‘36A.’

Hereafter, the pre-treatment 101 which hydroxytates the surface of the gate insulation layer 36 is described in detail.

First, a primary pre-treatment in which hydrogen gas (H₂) is applied is performed on the surface of the gate insulation layer 36. The primary pre-treatment may be performed at a temperature ranging from approximately 700° C. to approximately 1,200° C. under the pressure of approximately 100 mtorr to approximately 450 torr so that the hydrogen gas may be easily adsorbed onto the surface of the gate insulation layer 36.

After the primary pre-treatment, a secondary pre-treatment is performed by using a mixed solution of hydrogen peroxide (H₂O₂) and deionized water (DI, H₂O). Herein, the secondary pre-treatment, which is performed in succession to the primary pre-treatment, is performed in the same chamber in-situ. The secondary pre-treatment may be performed for approximately 5 minutes to approximately 30 minutes so that a sufficient amount of hydroxyl group (—OH) attaches to the surface of the gate insulation layer 36. To raise the efficiency of the hydroxyl group (—OH) being attached to the surface of the gate insulation layer 36, the secondary pre-treatment may be performed by adding aqueous ammonia (NH₄OH) to the mixed solution of hydrogen peroxide (H₂O₂) and deionized water (DI, H₂O). Herein, the aqueous ammonia (NH₄OH) includes ammonium hydroxide containing 4 to 16 carbon atoms. In addition, the aqueous ammonia added to the mixed solution may be mixed at a weight ratio of approximately 5 wt % to approximately 30 wt %.

Meanwhile, before the pre-treatment 101, inert gas such as helium (He) or argon (Ar) may flow into the chamber for a predetermined time to stabilize the atmosphere of the chamber.

Referring to FIG. 3C, an adhesive layer 37 is formed over the surface of the substrate structure including the hydroxylated gate insulation layer 36A. Herein, the adhesive layer 37 may include an early transition metal. An early transition metal is a transition metal that does not have an electron in a d orbit. Further, a characteristic of an early transition metal is that it forms a strong bond with a hydroxyl group (—OH). Therefore, the adhesive layer 37 may be formed through a Chemical Vapor Deposition (CVD) method to induce a smooth bond between the adhesive layer 37, including the early transition metal, and the hydroxylated gate insulation layer 36A.

To be specific, in order to form the adhesive layer 37 including the early transition metal through the CVD method, the adhesive layer 37 may be formed by using, as a source gas, a mixture of the early transition metal and at least one selected from the group consisting of hydrogen (H), chloride (Cl), bromine (Br) and alkoxide. Herein, hydrogen (H), chloride (Cl), bromine (Br), and alkoxide function as a ligand for the early transition metal. The ligand improves the coherence (or adhesion) between the hydroxylated gate insulation layer 36A and the adhesive layer 37. The early transition metal may be one selected from the group consisting of titanium (Ti), zirconium (Zr), hafnium (Hf), vanadium (V), niobium (Nb), and tantalum (Ta).

Because the surface of the gate insulation layer 36 is hydroxylated through the pre-treatment 101, the coherence (or adhesion) between the hydroxylated gate insulation layer 36A and the adhesive layer 37 may be improved.

Referring to FIG. 3D, a primary post-treatment 102 is performed to control the thickness of the adhesive layer 37 while removing residues and byproducts generated during the formation of the adhesive layer 37 at the same time. Hereafter, the adhesive layer 37 obtained after the primary post-treatment 102 is denoted with reference numeral ‘37A.’

Herein, the primary post-treatment 102 is performed until the adhesive layer 37A comes to have a thickness ranging from approximately 1 nm to approximately 5 nm. The thickness of the adhesive layer 37A is controlled in order to prevent the adhesive layer 37A from losing the characteristics desired to serve as a gate electrode. For example, the thicker the adhesive layer 37A becomes, the smaller volume the gate electrode will have in terms of resistivity. Therefore, there may be an adverse effect that the resistivity of buried gates may be increased.

The primary post-treatment 102 may be performed through a wet cleaning process, and the primary post-treatment 102 may be performed using one selected from the group consisting of sulfuric acid, perchloric acid (HClO₄), hydroiodic acid (HI), hydrobromic acid (HBr), hydrochloric acid (HCl), and nitric acid (NHO₃).

Referring to FIG. 3E, a secondary post-treatment 103 for removing the ligand remaining unbounded on the adhesive layer 37A is performed. In short, the secondary post-treatment 103 improves the binding force (or adhesion) between the adhesive layer 37A and the hydroxylated gate insulation layer 36A even more. Also, the secondary post-treatment 103 improves the binding force between a gate electrode, which will be formed in a subsequent process, and the adhesive layer 37A. Hereafter, the adhesive layer 37A obtained after the secondary post-treatment 103 is denoted with reference numeral ‘37B.’

The secondary post-treatment 103 may be performed by using a mixed gas of hydrogen gas (H₂) and ammonia gas (NH₃). Herein, to improve the reactivity between the mixed gas and the adhesive layer 37B, the secondary post-treatment 103 may be performed at a temperature ranging from approximately 700° C. to approximately 1,200° C. under the pressure of approximately 100 mtorr to approximately 450 torr. Herein, inert gas such as helium (He) or argon (Ar) may flow into the chamber in order to stabilize the atmosphere of the chamber during the primary post-treatment 102 and the secondary post-treatment 103.

Referring to FIG. 3F, a gate conductive layer formed of a single material is deposited over the adhesive layer 37B. Herein, the gate conductive layer includes a metallic layer, such as a titanium nitride (TiN) layer.

Subsequently, the gate conductive layer is etched through a blanket etch process to form a gate electrode 38 which fills a portion of each trench 35. Herein, the adhesive layer 37B may be etched while the gate electrode 38 is formed. Herein, the adhesive layer 37B has a thickness ranging from approximately 1 nm to approximately 5 nm. Since the adhesive layer 37B has a relatively thin thickness, due to the primary post-treatment 102, compared with the gate electrode 38, etch non-uniformity originating from the difference in etch selectivity between the adhesive layer 37B and the gate electrode 38 may be insignificant.

Subsequently, after an insulation layer is deposited over the profile of the substrate 31, a planarization process is performed until the upper surface of the hard mask pattern 34 is exposed to form a sealing layer 39 filling the remaining unfilled portion of each trench 35.

As described above, due to the pre-treatment 101, the formation of the adhesive layer 37, the primary post-treatment 102, and the secondary post-treatment 103, the adhesion between the gate electrode 38, which is formed of a single material, and the hydroxylated gate insulation layer 36A may be improved and the interface conditions may be stably maintained during thermal treatment performed at approximately 750° C. or higher.

According to an embodiment of the present invention, the adhesion between a gate electrode (or a conductive layer) and a gate insulation layer (or an insulation layer) may be improved by including an adhesive layer and at the same time stable interface conditions may be maintained even in a subsequent thermal process.

Also, according to an embodiment of the present invention, the adhesion between a gate electrode (or a conductive layer) and a gate insulation layer (or an insulation layer) may be improved by performing a pre-treatment and at the same time stable interface conditions may be maintained even in a subsequent thermal process.

Also, according to an embodiment of the present invention, the adhesion between a gate electrode (or a conductive layer) and a gate insulation layer (or an insulation layer) may be improved by performing a post-treatment and at the same time stable interface conditions may be maintained even in a subsequent thermal process.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming an insulation layer;
hydroxylating a surface of the insulation layer by performing a pre-treatment;
forming an adhesive layer over the insulation layer;
performing a post-treatment; and
forming a conductive layer over the adhesive layer.

2. The method of claim 1, wherein the insulation layer comprises a silicon oxide layer (SiO₂), and the conductive layer comprises a titanium nitride layer (TiN).

3. The method of claim 1, wherein the performing of the pre-treatment comprises:
performing a primary pre-treatment where hydrogen gas (H₂) is applied to the surface of the insulation layer; and
performing a secondary pre-treatment by using a mixed solution of hydrogen peroxide (H₂O₂) and deionized water (DI, H₂O).

4. The method of claim 3, wherein the primary pre-treatment is performed at a temperature ranging from approximately 700° C. to approximately 1,200° C. under the pressure of approximately 100 mtorr to approximately 450 torr.

5. The method of claim 3, wherein the secondary pre-treatment is performed by adding aqueous ammonia to the mixed solution.

6. The method of claim 3, wherein the secondary pre-treatment is performed for approximately 5 minutes to approximately 30 minutes.

7. The method of claim 3, wherein the secondary pre-treatment and the primary pre-treatment are performed in the same chamber in-situ.

8. The method of claim 1, wherein the adhesive layer comprises an early transition metal.

9. The method of claim 8, wherein the forming of the adhesive layer is performed by using a mixture of the early transition metal and at least one selected from the group consisting of hydrogen (H), chloride (Cl), bromine (Br), and alkoxide, as a source gas.

10. The method of claim 8, wherein the early transition metal comprises one selected from the group consisting of titanium (Ti), zirconium (Zr), hafnium (Hf), vanadium (V), niobium (Nb), and tantalum (Ta).

11. The method of claim 1, wherein the performing of the post-treatment comprises:
performing a primary post-treatment in which the adhesive layer is etched until the adhesive layer reaches a certain thickness; and
performing a secondary post-treatment by using a mixed gas of hydrogen gas (H₂) and ammonia gas (NH₃).

12. The method of claim 11, wherein the primary post-treatment is performed by using one selected from the group consisting of sulfuric acid, perchioric acid (HClO₄), hydroiodic acid (HI), hydrobromic acid (HBr), hydrochloric acid (HCl), and nitric acid (NHO₃).

13. The method of claim 11, wherein the secondary post-treatment is performed at a temperature ranging from approximately 700° C. to approximately 1,200° C. under the pressure of approximately 100 mtorr to approximately 450 torr.

14. A method for fabricating a semiconductor device, comprising:
forming a plurality of trenches by selectively etching a substrate;
forming a gate insulation layer on the plurality of the trenches;
hydroxylating a surface of the gate insulation layer by performing a pre-treatment;
forming an adhesive layer over the gate insulation layer;
performing a post-treatment; and
forming a gate electrode which fills a portion of each trench over the adhesive layer.

15. The method of claim 14, wherein the gate insulation layer comprises a silicon oxide layer (SiO₂), and the gate electrode comprises a titanium nitride layer (TiN).

16. The method of claim 14, wherein the performing of the pre-treatment comprises:
performing a primary pre-treatment where hydrogen gas (H₂) is applied to the surface of the gate insulation layer; and
performing a secondary pre-treatment by using a mixed solution of hydrogen peroxide (H₂O₂) and deionized water (DI, H₂O).

17. The method of claim 16, wherein the primary pre-treatment is performed at a temperature ranging from approximately 700° C. to approximately 1,200° C. under the pressure of approximately 100 mtorr to approximately 450 torr.

18. The method of claim 16, wherein the secondary pre-treatment is performed by adding aqueous ammonia to the mixed solution.

19. The method of claim 16, wherein the secondary pre-treatment is performed for approximately 5 minutes to approximately 30 minutes.

20. The method of claim 16, wherein the secondary pre-treatment and the primary pre-treatment are performed in the same chamber in-situ.

21. The method of claim 14, wherein the adhesive layer comprises an early transition metal.

22. The method of claim 21, wherein the forming of the adhesive layer is performed by using a mixture of the early transition metal and at least one selected from the group consisting of hydrogen (H), chloride (Cl), bromine (Br), and alkoxide, as a source gas.

23. The method of claim 21, wherein the early transition metal comprises one selected from the group consisting of titanium (Ti), zirconium (Zr), hafnium (Hf), vanadium (V), niobium (Nb), and tantalum (Ta).

24. The method of claim 14, wherein the performing of the post-treatment comprises:
performing a primary post-treatment in which the adhesive layer is etched until the adhesive layer reaches a predetermined thickness; and
performing a secondary pre-treatment by using a mixed gas of hydrogen gas (H₂) and ammonia gas (NH₃).

25. The method of claim 24, wherein the certain thickness of the adhesive layer is a thickness ranging from approximately 1 nm to approximately 5 nm.

26. The method of claim 24, wherein the primary post-treatment is performed by using one selected from the group consisting of sulfuric acid, perchloric acid (HClO₄), hydroiodic acid (HI), hydrobromic acid (HBr), hydrochloric acid (HCl), and nitric acid (NHO₃).

27. The method of claim 24, wherein the secondary post-treatment is performed at a temperature ranging from approximately 700° C. to approximately 1,200° C. under the pressure of approximately 100 mtorr to approximately 450 torr.

28. A semiconductor device, comprising:
a substrate having a trench;
a hydroxylated gate insulation layer in the trench;
an adhesive layer over the hydroxylated gate insulation layer; and
a gate electrode, which fills a portion of the trench over the adhesive layer.

29. The semiconductor device of claim 28, wherein the hydroxylated gate insulation layer comprises a silicon oxide layer (SiO₂), the adhesive layer comprises an early transition metal, and the gate electrode comprises a titanium nitride layer (TiN).
